(19) United States
(12) Patent Application Publication
(10) Pub. No.: US 2017/0161418 A1
(43) Pub. Date: Jun. 8, 2017

(54) USING THREE-DIMENSIONAL REPRESENTATIONS FOR DEFECT-RELATED APPLICATIONS

(71) Applicant: KLA-Tencor Corporation, Milpitas, CA (US)

(72) Inventors: Allen Park, San Jose, CA (US); Ellis Chang, Saratoga, CA (US); Prashant A. Aji, San Jose, CA (US); Steven R. Lange, Alamo, CA (US)

(21) Appl. No.: 15/437,409

(22) Filed: Feb. 20, 2017

Related U.S. Application Data
(63) Continuation of application No. 13/156,323, filed on Jun. 8, 2011, now abandoned.

(51) Int. Cl. G06F 17/50; G01N 21/95

(52) U.S. Cl. CPC G06F 17/5068; G06F 17/5009; G01N 21/9501; G06F 2217/12; H01L 22/12

(57) ABSTRACT

Various embodiments for using three-dimensional representations for defect-related applications are provided. One computer-implemented method for determining one or more inspection parameters for a wafer inspection recipe includes generating a three-dimensional representation of one or more layers of a wafer based on design data. The method also includes determining one or more inspection parameters for a wafer inspection recipe based on the three-dimensional representation.

### BACKGROUND OF THE INVENTION

Field of the Invention

The present invention generally relates to using three-dimensional representations for defect-related applications.

Description of the Related Art

The following description and examples are not admitted to be prior art by virtue of their inclusion in this section.

Inspection processes are used at various steps during a semiconductor manufacturing process to detect defects on wafers to promote higher yield in the manufacturing process and thus higher profits. Inspection has always been an important part of fabricating semiconductor devices. However, as the dimensions of semiconductor devices decrease, inspection becomes even more important to the successful manufacture of acceptable semiconductor devices because smaller defects can cause the devices to fail.

Recently, efforts have been made to incorporate design data in various defect-related processes such as inspection, defect classification, defect review, and defect binning While these efforts have, in general, added significant value to defect-related. applications, these approaches can be improved in a number of ways. For example, because inspection setup, binning and review are based on two-dimensional (2D) or “top down” views of design data, inspection and review strategies are limited by the amount of information provided by those top-down views. Defect binning is limited to such top views as well. Therefore, defects that are important from a three-dimensional (3D) aspect, both from the cross-sectional view of the inspected layer as well as future layers to be formed on the inspected layer subsequent to inspection, cannot be taken into consideration when setting up inspection, metrology, defect binning or review or performing physical analysis.

Accordingly, it would be advantageous to develop methods and systems for using 3D representations of design data for defect-related applications.

### SUMMARY OF THE INVENTION

The following description of various embodiments is not to be construed in any way as limiting the subject matter of the appended claims.

One embodiment relates to a computer-implemented method for determining one or more inspection parameters for a wafer inspection recipe. The method includes generating a three-dimensional (3D) representation of one or more layers of a wafer based on design data. The method also includes determining one or more inspection parameters for a wafer inspection recipe based on the 3D representation. Generating the 3D representation and determining the inspection parameter(s) are performed by a computer system.

Each of the steps of the method described above may be further performed as described herein. In addition, the method described above may include any other step(s) of any other method(s) described herein. Furthermore, the method described above may be performed by any of the systems described herein.

Another embodiment relates to a non-transitory computer-readable medium containing program instructions stored therein for causing a computer system to perform a computer-implemented method for determining one or more inspection parameters for a wafer inspection recipe. The computer-implemented method includes the steps of the method described above. The computer-readable medium may be further configured as described herein. The steps of the method may be performed as described further herein. In addition, the method may include any other step(s) of any other method(s) described herein.

An additional embodiment relates to a system configured to determine one or more inspection parameters for a wafer inspection recipe. The system includes a simulation engine configured to generate a 3D representation of one or more layers of a wafer based on design data. The system also includes a computer system configured to determine one or more inspection parameters for a wafer inspection recipe based on the 3D representation. The system may be further configured according to any embodiment(s) described herein.

### BRIEF DESCRIPTION OF THE DRAWINGS

Further advantages of the present invention will become apparent to those skilled in the art with the benefit of the following detailed description of the preferred embodiments and upon reference to the accompanying drawings in which:

FIG. 1 is a schematic diagram illustrating a two-dimensional representation of one layer of a wafer based on one example of design data;

FIG. 2 is a schematic diagram illustrating one embodiment of a three-dimensional representation of one or more layers of a wafer based on one example of design data;

FIG. 3 is a Hock diagram illustrating one embodiment of a non-transitory computer-readable medium; and

FIGS. 4-5 are schematic diagrams illustrating side views of embodiments of a system configured to determine one or more inspection parameters for a wafer inspection recipe.

While the invention is susceptible to various modifications and alternative forms, specific embodiments thereof are shown by way of example in the drawings and are herein described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims,

### DETAILED DESCRIPTION OF THE PREFERRED EMBODIMENTS

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals.

In general, the embodiments described herein use a three-dimensional (3D) representation of one or more layers of a wafer for defect-related applications. One embodiment relates to a computer-implemented method for determining one or more inspection parameters for a wafer inspection recipe. The method includes generating a 3D representation of one or more layers of a wafer based on design data. The one or more layers may include one or more mask layers or process layers such as active layer(s), poly layer(s), contact layer(s), metal layer(s), etc. In addition, the one or more layers may include layer(s) such as short-loop photoresist, shallow trench isolation layer(s), etc. A layer may he formed on the wafer using any suitable wafer fabrication process such as lithography, etch, deposition, chemical-mechanical polishing (CMP), or any other process that can alter the structure of the wafer.

The 3D representation may be a 3D visualization generated using both a design layout file as well as a 3D visualization tool such as technology for computer-aided design (TCAD) and spectra critical dimension (SCD) modeling. The 3D representation may be generated using graphical simulation models such as those described in U.S. Patent Application Publication No. 2005/0113951 to Akiyama et al. and U.S. Pat. No. 7,131,076 to Sherstyuk et al. and U.S. Pat. No. 7,792,595 to Bomholt et al., TCAD such as TCAD-based products commercially available from Synopsys, Mountain View, Calif., or SCD models such as the 3D shape models used in the AcuShape2 product commercially available from KLA-Tencor, Milpitas, Calif. The 3D representation may also be generated as described in commonly owned U.S. patent application Ser. No. 12/154,917 by Steven Lange filed May 28, 2008, which is incorporated by reference as if fully set forth herein. In this manner, the embodiments described herein can leverage existing technology currently available in SCD and TCAD tools. The 3D representations can be used in a number of ways described further herein. In this manner, the embodiments described herein take advantage of the 3D nature of devices. For example, the 3D representation provides enhanced insight into device structures that can be used in a number of ways described further herein such as advanced inspection setup techniques.

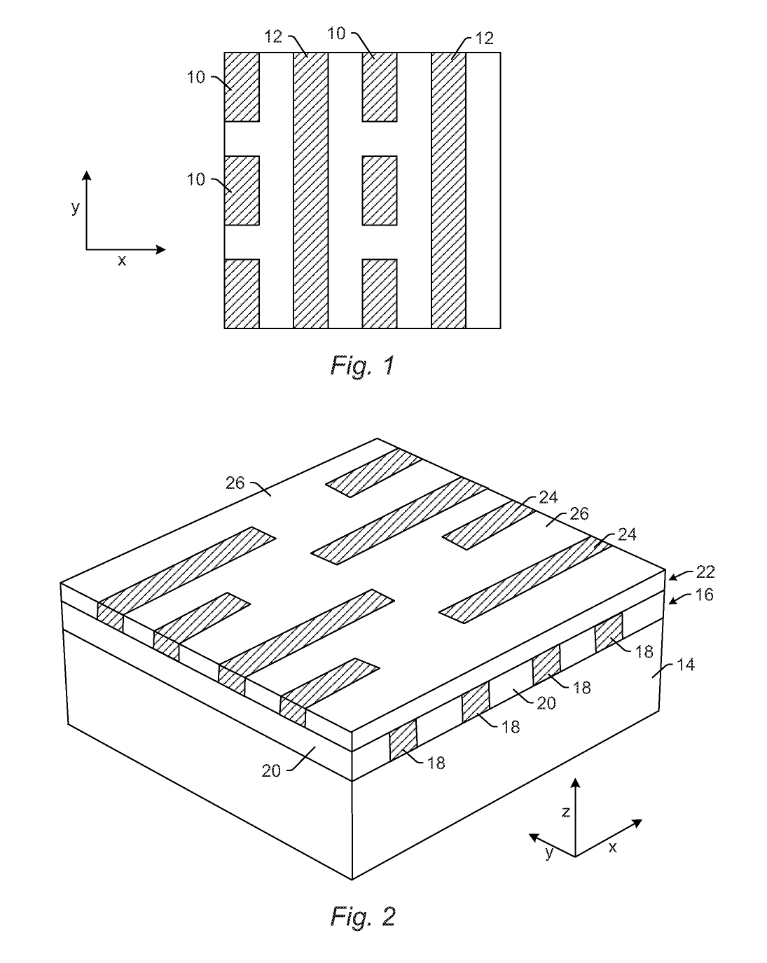

FIG. 1 illustrates a two-dimensional (2D) representation of one layer of a wafer based on one example of design data. The design data shown in FIG. 1 is not meant to represent any actual design data that is, has been, or will be used to fabricate devices. As shown in FIG. 1, the design data may include a plurality of polygons that represent different features that will be formed on one layer of a wafer. The features may include shorter lines 10 and longer lines 12. As can be seen from FIG. 1, various information about the layer can be determined from the 2D representation such as locations of the features in two dimensions (x and y), spacings between the features in two dimensions (x and y), dimensions of the features in two dimensions (x and y), and the like. However, as can also be seen from FIG. 1, no information about the layer in the z direction can be determined from the 2D representation.

In contrast, FIG. 2 illustrates a 3D representation of one or more layers of a wafer based on one example of design data. The design data shown in FIG. 2 is not meant to represent any actual design data that is, has been, or will be used to fabricate devices. As shown in FIG. 2, the design data may include a plurality of polygons that represent different features that will be formed on the one or more layers. Layer 14 may represent the wafer or the substrate of the wafer. Layer 16, which is formed on layer 14, may include trenches 18 formed in material 20. Layer 18 is formed under layer 22, which includes lines 24 having various sizes and locations formed in material 26. As can be seen from FIG. 2, various information about the layers can be determined from the 3D representation such as locations of the features in three dimensions (x, y, and z), spacings between the features in three dimensions (x, y, and z), dimensions of the features in three dimensions (x, y, and z), and the like. Therefore, as can be seen from comparison of FIGS. 1 and 2, information about the layer(s) in the z direction can be determined from the 3D representation but not the 21) representation.

In one embodiment, the one or more layers include a first layer that will be inspected using the wafer inspection recipe and a second layer formed on the wafer before the first layer is formed on the wafer, In this manner, the one or more layers may include the inspected layer (i.e., the layer that will be inspected) and at least one layer underlying the inspected layer (i.e., a layer formed on the wafer before the inspected layer). For example, the inspected layer may include a layer of lines formed in a dielectric material, and the underlying layer may include a gate electrode layer, which in of itself may be formed of multiple materials and in multiple processes, and which is formed on the wafer before the inspected layer and underneath the inspected layer.

In another embodiment, the one or more layers include a layer that will be inspected using the wafer inspection recipe and a layer that is not formed on the wafer before the wafer is inspected using the wafer inspection recipe. In this manner, the methods may include using one or more future design layout layers for applications described herein such as inspection, binning, review, etc. through 3D simulation. For example, the one or more layers may include the inspected layer (i.e., the layer that will be inspected) and at least one layer that will be formed after inspection and on top of the inspected layer. For example, the one or more layers may include a metal 1 (M1) layer that will be inspected and a metal 2 (M2) layer that will be formed on the wafer after the M1 layer has been inspected, will be formed on top of the M1 layer, and in of itself may be formed of multiple materials and in multiple processes. In addition, the one or more layers for which the 3D representation is generated may include the layer that will be inspected, at least one layer formed on the wafer before that layer, and at least one layer that is not formed on the wafer before inspection is performed on the wafer. The 3D representation may also be generated such that layers can be added to and/or removed from the 3D representation such that the 3D representation can be altered, for example, based on a request received from a user. Such functionality can be used to provide a 3D visualization of the formation of the individual layers on the wafer and how the layers correspond to one another.

The method also includes determining one or more inspection parameters for a wafer inspection recipe based on the 3D representation. A “recipe” may be generally defined as a set of instructions for carrying out a process such as inspection. Determining one or more inspection parameters for a wafer inspection recipe may include selecting or determining a value for at least one parameter of the wafer inspection recipe. The term “inspection parameter” is used herein to refer to all of the variables that are used to setup an inspector such as wavelength(s), pixel, care area, speed, illumination and collection apertures, etc. For example, the parameter(s) for the wafer inspection recipe may include a parameter of an inspection system used to acquire output responsive to light from the wafer and/or a parameter of the inspection system used to process the output. In this manner, the parameter(s) may include output acquisition parameter(s) and/or output processing parameter(s). In one such example, TCAD can be used to analyze the area of the wafer that will be inspected to select wafer inspection parameter(s) based on the morphology of layers and film stacks on the wafer. The wafer inspection recipe may be a dark field (DF) inspection recipe, a bright field (BF) inspection recipe, an electron beam (e-beam) inspection recipe, or a DF and BF inspection recipe. The parameter(s) of the wafer inspection recipe may be further determined as described herein.

The method, therefore, involves generating a 3D-based wafer inspection recipe. In contrast, currently used methods for generating a wafer inspection recipe may be based on a 2D view of the wafer such as top-down optical images or top-down scanning electron microscope (SEM) images. Previously, no link has been established between 3D representations and defect inspection methods. However, with the focus on shrinking the 2D characteristics and vertical integration of semiconductor devices, 3D visualization can help set up wafer inspection by defining wafer inspection parameters better. In this manner, the embodiments described herein provide a method of leveraging design layout and existing technologies such as 3D visualization technology to introduce a new capability and dimension in wafer inspection and defining wafer inspection recipes. In particular, the embodiments described herein may use important components such as defect inspection, design layout, and 3D visualization techniques such as TCAD process simulation tools. In addition, by leveraging 3D visualization tools such as TCAD and SCD modeling, wafer inspection parameters can be optimized by providing accuracy and more insight into how the active circuitry in design data is laid out on a wafer. In this manner, design layout and 3D visualization tools can be used in conjunction to optimize wafer inspection parameter setting.

Generating the 3D representation and determining the one or more inspection parameters are performed by a computer system. The computer system may be further configured as described herein.

In one embodiment, the one or more inspection parameters include at least one parameter of an illumination subsystem used to perform the wafer inspection recipe, at least one parameter of a light detection subsystem used to perform the wafer inspection recipe, or some combination thereof. For example, TCAD can be used to analyze the design data for the area of the wafer to be inspected to select optics settings to be used for wafer inspection based on the morphology of layers on the wafer and film stacks on the wafer. In addition, the 3D representation (e.g., generated by TCAD or graphical simulation) can help setup wafer inspection by understanding potential illumination behavior. For example, when a surface is illuminated, some of the light energy is absorbed while the rest is reflected. The reflected energy can be used to identify materials on a wafer since various materials have different responses to a given type of illumination. However, information about what materials) is/are on the surface of a wafer and below the surface can be used to define the most suitable optics for the best detection of defects (e.g., based on the different responses of various materials to a given type of illumination).

Wafer inspection parameters such as optics mode, pixel size, etc can also be selected based on the 3D representation of the one or more layers. In one such example, 3D structures included in a 3D representation and material information can be used to recommend a number of inspection modes that may be the best (e.g., the 3 best inspection modes). For example, using a 3D representation of design data and material information, possibly in combination with other information such as a 2D view of the design data, information about potential defects of interest (DOIs) on the wafer such as DOI size and material information, location/layer of DOI, etc. can be determined. That information can then be used to determine and recommend the best optics mode(s) for detecting those DOIs. Inspection results can be collected using the recommended mode(s) and the results can be correlated to bitmap for optimized hit ratio.

In another example, 3D representations of potential defects may be used to set up inspection. For example, a 3D representation of a defective deep trench (DT) and a non-defective DT may be generated. A non-defective DT may be a DT that is etched into the substrate of a wafer. A defective DT may be a DT that is not etched all the way into the substrate of the wafer. Since most defective DTs are in contact with layers such as silicon-on-insulator (SOI) that are similar to the substrate, defective and non-defective DTs cannot he easily differentiated by certain types of inspection such as e-beam inspection. Therefore, for setting up DT inspection, knowing the cross-sectional (3D) information about the features helps to set up defect inspection. In this manner, using 3D modeling, a better strategy can be defined without having to obtain a cross-sectional SEM image of the potential defects.

The one or more parameters of the illumination subsystem may include, for example, angle(s) of illumination, wavelength(s) of illumination, polarization(s) of illumination, spot size, aperture(s) included in the illumination subsystem, other optical component(s) included in the illumination subsystem, and combinations thereof. The one or more parameters of the light detection subsystem may include, for example, angle(s) of collection, wavelength(s) of detection, polarization(s) of detection, pixel size, aperture(s) included in the detection subsystem, other optical component(s) included in the detection subsystem, and combinations thereof. Similar parameter(s) can be determined for non-light based wafer inspection systems (e.g., electron beam inspection systems). In one such example, 3D information such as the aspect ratios of features formed in at least one of the layers may be used to determine the angle(s) of illumination and the angle(s) of collection used for wafer inspection. In particular, as the aspect ratios of the features increase, the angle(s) of incidence and the angle(s) of collection used for wafer inspection may also be increased (as measured from the nominal wafer surface). The illumination subsystem and the light detection subsystem may be configured as described further herein.

In another embodiment, the one or more inspection parameters include one or more parameters used for processing output generated by a light detection subsystem used to perform the wafer inspection recipe. For example, the output generated by the light detection subsystem may include images or image data, and the one or more inspection parameters may include one or more parameters used to filter, align, etc. the images or image data. In another example, the output may include signals, and the one or more inspection parameters may include one or more parameters used for filtering, normalizing, calibrating, etc. the signals. The one or more inspection parameters used for processing the output may be determined separately for different areas on the wafer. For example, output generated in one area of the wafer may be processed using one or more first inspection parameters, and output generated in another area of the wafer may be processed using one or more second inspection parameters, at least some of which may be different than the first inspection parameter(s). The light detection subsystem may be configured as described further herein.

In an additional embodiment, the one or more inspection parameters include a defect detection sensitivity for the wafer inspection recipe. For example, using the design layout n 3D view (e.g., by using TCAD to generate a 3D representation) and linking wafer inspection parameters to the 3D view, detection sensitivity can be optimized for critical regions within a device and/or the noise level in the output generated by the inspection system for the wafer. The defect detection sensitivity may be defined by one or more inspection parameters (e.g., a threshold) of a defect detection algorithm and/or method. In addition, the one or more inspection parameters may include different detection sensitivities for different areas of the wafer (e.g., higher sensitivity for critical areas and lower sensitivity for non-critical areas). The detection sensitivity can be determined based on the 3D representation in any suitable manner. For example, the 3D representation can be used to determine critical regions on the wafer, and then the defect detection sensitivity can be determined based on the criticality of those critical regions. In another example, the 3D representation can be used to determine the expected noise levels of the output of the inspection system that will be generated for the wafer and then the expected noise levels can be used to determine the defect detection sensitivity.

In a further embodiment, the one or more inspection parameters include one or more characteristics of inspection care areas on the wafer. The term “inspection care areas” can be generally defined as areas on the wafer that a user cares about for some reason and therefore should be inspected. Currently, inspection care areas may be determined based on 2D design data for a layer on a wafer. In one such example, inspection care areas for one layer of the wafer may be defined such that the inspection care areas include critical features that are formed on the one layer and do not include non-critical features that are formed on the layer. However, non-critical features on one layer may overlay critical features of another layer formed under the one layer. Therefore, if a 3D representation is generated for the layer and the underlying layer, then the areas in which the non-critical features are formed over critical features may be determined to be inspection care areas based on the 3D representation. In this manner, a 3D representation (or visualization) generated as described herein may be used to identify underlying structures during inspection care area setup. Therefore, based on the 3D representation, inspection care areas may be defined more appropriately for the device as a whole and the inspection care areas may include some areas that would be determined based on 2D data to be non-care areas. As such, the wafer inspection parameters may be selected based on the 3D characteristics of structures on more than one layer of the wafer. Defining the inspection care areas as described above may advantageously increase detection of defects that are meaningful from a device functionality perspective.

In one embodiment, determining the one or more inspection parameters is performed based on the 3D representation and information about one or more materials that are used to form the one or more layers. In this manner, wafer inspection setup may be performed using materials information. For example, by using area information in 2D and 3D along with materials data, an optimized wafer inspection mode can be identified. In one such embodiment, the information about the one or more materials includes computed surface response, reflectivity, or the combination thereof. For example, 3D materials data such as the complex index of refraction and thickness of a material that will form at least part of a layer that will be present on a wafer during inspection can be used to determine one or more parameters of an illumination subsystem and/or detection subsystem that will be appropriate for detecting defects on that part of the layer. The wafer inspection recipe may be generated in any suitable format (such as a file format that can be used by a wafer inspection system).

In a further embodiment, the method includes extracting 2D design data clips for defects detected using the wafer inspection recipe and while the wafer is being inspected using the wafer inspection recipe, generating 3D representations for the defects based on output acquired for the defects using the water inspection recipe and the 2D design data clips. The term “design data clip” as used herein refers to a relatively small portion of the design data. In this manner, wafer inspection may include using 2D clip extraction to generate a 3D representation in real-time. The 2D design data clips extracted for the defects may include 2D design data for one or more layers of the wafer (e.g., the inspected layer only or the inspected layer and an underlying layer and/or an overlying layer). The 2D design data clips may be extracted in any appropriate manner from the design data for the wafer. In addition, generating the 3D representations for the detects based on the output acquired for the defects and the 2D design data clips may he performed in the same manner as described above (e.g., using WAD). In this manner, the 3D representations generated for the defects may be different than other 3D representations described herein in that the defect 3D representations may illustrate the defects themselves as well as the one or more layers in three dimensions. These 3D representations of the defects can be used for other step(s) described herein (e.g., defect classification).

The defect 3D representations described above may also be generated at any desired point (e.g., not just in real-time). In any case, the defect 3D representations provide greater availability of pattern information near defects. For example, previously, 3D pattern information for defects was only available from SEM imaging and FIB data for sampled defects. In particular, wafer inspection may detect about 1,000 to 1,000,000 defects on a wafer. Typically, for those detected defects, perhaps 100 SEM images may be generated and fewer than 10 cross-section images may be generated. However, the 3D representations described herein can be generated for any defects, sampled or not. In this manner, top-down views and/or cross-section images may he generated for any of the detected defects dynamically or otherwise. Therefore, both top-down and cross-sectional views can be generated and be made available independent of defect review sampling.

In one embodiment, generating the three-dimensional representation is performed dynamically. For example, the 3D representations and the defect 3D representations also provide additional technical data that can be made available for fab users. In particular, device and defect cross-sections are typically available through documents for diagnosis. Such views of the device are typically only available for fixed locations in the device. However, the 3D representations and the 3D defect representations described herein can be generated at virtually any location in the device, for which defect information and/or design data is available, at any view(s). In this manner, the embodiments described herein allow the device to be better visualized through 3D view(s) for better understanding at dynamic locations within the device.

In one embodiment, the method includes inspecting the wafer using the wafer inspection recipe, which may be performed in any suitable manner using any suitable wafer inspection system such as those described further herein, and classifying defects detected on the wafer by the inspecting based on the 3D representation. In an additional embodiment, the one or more layers include a layer that is inspected using the wafer inspection recipe and a layer that is not formed on the wafer before the wafer is inspected using the wafer inspection recipe, and the method includes classifying a defect detected on the wafer using the wafer inspection recipe based on the 3D representation of the layer that is inspected and the layer that is not formed on the wafer. For example, a nuisance defect that can cause bridging or an open in a future layer (a layer not formed on the wafer at the time of inspection) can be classified as a nuisance when only 2D data (the current layer) is considered. However, using the embodiments described herein, by overlaying information about layers formed on the wafer after the inspected layer with design layouts at current inspection and review levels via the 3D representation, defects that land on critical regions based on future layers can be immediately identified even before the next wafer inspection is performed.

In addition, the 3D representation may be generated based on the design data in combination with information about the defects generated by wafer inspection (e.g., image data, signals, etc.), and the 3D representation incorporating the defect information may be used to classify the defects. As such, the method may integrate 2D-based wafer inspection results and 3D representations for improved defect classification, For example, a defect may be identified in 2D by inspection, and information generated by inspection can be used as described herein to generate a 3D representation of the defect and one or more layers (e.g., prior and future layers) on the wafer. Such a 3D representation may be used to perform virtual failure analysis (FA). In other words, FA can be performed as it is normally performed except using a virtual 3D image of the defect instead of a 3D image obtained by FIB or another cross-sectional imaging technique. As such, the device impact of the defect can be determined without actually cross-sectioning or otherwise processing the wafer, and the defect can be classified based on 3D attributes. In this manner, the method may include 3D-based defect classification. In contrast, currently used methods for classifying defects are generally based on a 2D view of the defects such as optical or SEM images. In other words, previously, no link has been established between 3D representations and defect classification.

In some embodiments, the method includes inspecting the wafer using the wafer inspection recipe, which may be performed in any suitable manner using any suitable wafer inspection system such as those described further herein, and determining a criticality of defects detected on the wafer by the inspecting based on the 3D representation (e.g., at least the 3D representation). In a further embodiment, the one or more layers include a layer that is inspected using the wafer inspection recipe and a layer that is not formed on the wafer before the wafer is inspected using the wafer inspection recipe, and the method includes determining criticality of a defect detected on the wafer using the wafer inspection recipe based on the 3D representation of the layer that is inspected and the layer that is not formed on the wafer. In another embodiment, the one or more layers include a layer that is inspected using the wafer inspection recipe, a layer that is not formed on the wafer before the wafer is inspected using the wafer inspection recipe, and a layer that is formed on the wafer before the layer that is inspected using the wafer inspection recipe is formed on the wafer, and the method includes determining a criticality of a defect detected on the wafer using the wafer inspection recipe based on the 3D representation of the layer that is inspected, the layer that is not formed on the wafer, and the layer that is formed on the wafer before the layer that is inspected. For example, with requirements for inspection sensitivity continually increasing, nuisance defect detection is also continually on the rise. Criticality of certain defects such as line thinning or shortening depends on an understanding of other layers (e.g., underlying layer(s) or overlying layer(s)) on the wafer. For example, line thinning and line shortening are generally considered nuisance defects by many currently used wafer inspection processes. Therefore, such defects are generally not reported and are certainly not determined to be critical defects. However, if the line thinning or shortening affects the connectivity of the lines to other features on other layer(s) of the wafers, which can be determined based on the characteristics (e.g., extent) of the line thinning or shortening and the 3D representations described herein, the line thinning or shortening could be critical even though 2D inspection would typically determine such defects to be nuisance. Therefore, using a 3D representation of the design layout data combined with defect data can help identify ritical defects that could not be identified before.

In another embodiment, the method includes inspecting the wafer using the wafer inspection recipe, which may be performed in any suitable manner using any suitable wafer inspection system such as those described further herein, and determining which defects detected on the wafer by the inspecting are yield relevant defects based on the 3D representation. In this manner, the embodiments described herein provide a method of leveraging design layout and 3D visualization technology to identify yield relevant defects. For example, by using the 3D representations described herein as well as defect data, the effect a defect will have on the device being formed on the wafer can be determined in three dimensions thereby allowing all of the defects that will affect yield of the manufacturing process to be determined.

In one such example, similar patterns on one layer of the wafer can be separated from each other based on patterns on a different (e.g., underlying) layer. In addition, different line thinning defects and/or different feature deformations on one layer of the wafer may have different impacts on the device. For example, proximity of the defects to contacts or the same structures in different areas of the device may have varying impacts on the device. In addition, line end shortening may be nuisance or have adverse impacts on yield, and such defects may be separated as nuisance or yield impacting defects based on the 3D representations described herein. In some embodiments, design based grouping may be performed based on information for a single layer (e.g., the inspected layer) to combine different defects, Which are located on or near the same patterned features, in one group. The defects in that group may then he separated by using the 3D representations described herein for critical/non-critical separation. Design based grouping can be performed as described in commonly owned U.S. Pat. No. 7,570,796 to Zafar et al. issued on Aug. 4, 2009, which is incorporated by reference as if fully set forth herein.

In some embodiments, the method includes determining one or more parameters for binning defects detected on the wafer using the wafer inspection recipe based on the 3D representation. Binning is the process of classifying defects into groups or types that are similar or might have similar effects on the device performance. For example, determining the one or more parameters for binning defects may include defining the “expected” patterns (i.e., patterns expected to be formed on the wafer) using material information and simulation described herein such that the expected patterns can be used to identify defects located among similar patterns. The expected patterns may include underlying structures identified by the 3D representations described herein. In one such example, the expected patterns can be compared to the collected data (collected by SEM or DF imaging) to separate critical dimension (CD) defects from line edge roughness (LER) defects. Separating the defects in such a manner may be particularly advantageous for defects detected in array areas. For example, relatively narrow spaced lines typically found in array areas are challenging for both inspection and printing. In particular, defects in array areas are difficult to distinguish using traditional approaches. However, using the embodiments described herein, in which 3D representations are used in combination with inspection, events detected by inspection such as defects, CD errors, and can be identified and separated from each other. The different events can then be separately processed in the most appropriate manner. For example, defects can be sampled for review, CD errors can be sampled for metrology, and line edge roughness can be eliminated from further consideration or processing (i.e., these events can be “binned out”) or fixed. In addition, design layout and 3D visualization tools can be used in conjunction to create a flow for binning,

In this manner, the embodiments may include generating a 3D-based binning method. In contrast, currently used methods for generating a binning method are generally based on a 2D view of the wafer such as optical or SEM images. In addition, previously, no link has been established between 3D representations and binning methods. For example, previously, integrating design layout and defect inspection has been established by design based binning. While those techniques are useful, the technology was generally limited to leveraging 2D information, and the new approaches described herein introduce 3D analysis approaches by using both design-defect integration and 3D visualization techniques. In addition, although currently used binning methods may utilize design data for more than one layer of the wafer to bin defects, the design data used in previously used binning methods did not actually include 3D information, representations, visualizations, etc. Instead, the binning methods used the combination overlay) of 2D design data, and that combined 2D design data, in of itself, does not constitute a 3D representation of the design data.

The methods described herein may also include binning defects into groups based on at least the 3D representation (e.g., possibly in combination with other information about the defects such as defect attributes, features, etc., information about the inspection data for the defects such as inspection images, noise in the inspection data, etc.). Therefore, the embodiments may include 3D-based binning In contrast, currently used methods for binning defects are generally based on a 2D view of the wafer such as optical or SEM images. In addition, previously, no link has been established between 3D representations and defect binning. 3D-based binning may be used to separate defects in different types of areas on the wafer. For example, taking advantage of SCD technology, separation of defect types in memory areas may be possible.

In another embodiment, the method includes determining one or more parameters for review of defects detected on the wafer using the wafer inspection recipe based on the 3D representation. In this manner, the embodiments may include generating a 3D-based review process. As such, the embodiments described herein provide a method of leveraging design layout and 3D visualization technology to introduce a new capability in defining review. in other words, by leveraging existing technologies, a new dimension can be added in the review area. In addition, by leveraging 3D visualization tools such as TCAD and SCD modeling, defect review (e.g., SEM review) can be improved and even optimized by providing accuracy and more insight into how the active circuitry is laid out. In contrast, currently used methods for generating a review process are generally based on a 2D view of the wafer such as optical or SEM images. Previously, no link has been established between 3D representations and review methods.

In another embodiment, the method includes performing a defect review process on the wafer subsequent to inspecting the wafer using the wafer inspection recipe and determining which defects reviewed on the wafer by the defect review process are yield relevant defects based on the 3D representation. In an additional embodiment, the method includes performing a defect review process on the wafer subsequent to inspecting the wafer using the wafer inspection recipe and classifying defects reviewed on the wafer by the defect review process based on the 3D representation. For example, the methods described herein may include reviewing defects based on at least the 3D representation (e.g., possibly in combination with other information about the defects such as defect attributes, features, etc., information about the wafer inspection and/or review data for the defects such as inspection and review images, noise in the inspection data, etc.). For example, SEM-based review identities the relevance of defects to the current layer (i.e., the layer on which defects are being reviewed). By reviewing the defects with respect to future and/or previous layers, yield relevant defects can be identified and classified (as bridging, contact issues, broken lines, etc.). Therefore, the embodiments may include 3D-based defect review. In contrast, currently used methods for reviewing defects are generally based on a 2D view of the water such as optical or SEM images. Previously, no link has been established between 3D representations and defect review.

In an additional embodiment, the method includes determining one or more parameters for metrology of defects detected on the wafer using the wafer inspection recipe based on the 3D representation. The pararneter(s) of metrology that can be determined based on the 3D representation may include illumination wavelength(s), angle(s), polarization(s), etc., detection wavelength(s), angle(s), polarization(s), etc., which features are to be measured during metrology, which measurements are to be performed during metrology (e.g., scatterometry, reflectometry, ellipsometry, etc.), sampling frequency to be used during metrology, signal processing to be used to determine one or more characteristics from measurements obtained during metrology, and combinations thereof. In this manner, the one or more parameters of metrology may include output acquisition parameter(s) and/or output processing parameter(s). The parameter(s) for metrology may be determined based on the 3D representation as described further herein.

In one embodiment, the method includes determining one or more parameters for analysis of defects detected on the wafer using the wafer inspection recipe based on the 3D representation. The analysis of the defects may include physical analysis such as focused ion beam (FIB) analysis and physical failure analysis (PFA). For example, for defects that are to be physically analyzed, the method may include utilizing a 3D representation of the layer(s) to define how to best cut the cross-section used for physical analysis thereby enabling a more relevant view of the cross-section. In one such example, for a defect impacting a contact or metal line or adjacent to certain parts of the transistor, the parameters of analysis such as where and how to cut the layer(s) formed on the wafer may be selected based on the 3D representation to optimize the view of the defect provided by the cut. As such, a 3D visualization generated based on the design layout (e.g., generated using TCAD) can be used to identify where to cut thereby reducing faulty cuts and improving data acquisition for analysis such as FIB analysis or PFA. Therefore, more accurate cutting can be done by visualizing the 3D structures. As such, the embodiments described herein may provide a productivity improvement for PFA through more accurate cutting. In this manner, by leveraging 3D visualization tools such as TCAD and SCD modeling, defect physical analysis can be improved by providing accuracy and more insight into how the active circuitry is laid out. In addition, the 3D representation used to determine the one or more parameters for defect analysis may be generated based on the design data in combination with information about the defects generated by wafer inspection (e.g., image data, signals, etc.), and the 3D representation incorporating the defect information may be used for PFA. As such, the method may integrate 2D-based wafer inspection results and 3D representations for improved PFA. In this manner, the embodiments may include generating a 3D-based physical analysis process. In other words, by leveraging existing technologies, a new dimension can be added in the physical analysis area. In this manner, the embodiments described herein provide a method of leveraging design layout and 3D visualization technology to improve physical analysis.

The 3D representations described herein can also be used for process window optimization. For example, generating the 3D representation may be performed based on one or more process conditions that will be used to form the one or more layers on the wafer. Therefore, by varying the process conditions used to generate the 3D representations, 3D representations that illustrate how the one or more layers will be formed on the wafer at the different process conditions can be generated. The 3D representations can then be used to determine the process window thereby generating a simulated process window. The one or more layers can then be formed on the wafer using the actual process conditions within the simulated process window thereby running confirmation conditions. The one or more layers can then be inspected as described herein or in any other manner to generate inspection results that can be used to validate the simulated process window.

All of the methods described herein may include storing results of one or more steps of the method embodiments in a non-transitory, computer-readable storage medium. The results may include any of the results described herein and may be stored in any manner known in the art. The storage medium may include any storage medium described herein or any other suitable storage medium known in the art. After the results have been stored, the results can be accessed in the storage medium and used by any of the method or system embodiments described herein, formatted for display to a user, used. by another software module, method, or system, etc. For example, after the method determines the one or more inspection parameters for the wafer inspection recipe, the method may include storing the wafer inspection recipe in a storage medium. In addition, results or output of the embodiments described herein may be stored and accessed by a wafer inspection system such as those described further herein such that the wafer inspection system can use the wafer inspection recipe for inspection.

Each of the embodiments of the method described above may include any other step(s) of any other method(s) described herein. In addition, each of the embodiments of the method described above may be performed by any of the systems described herein.

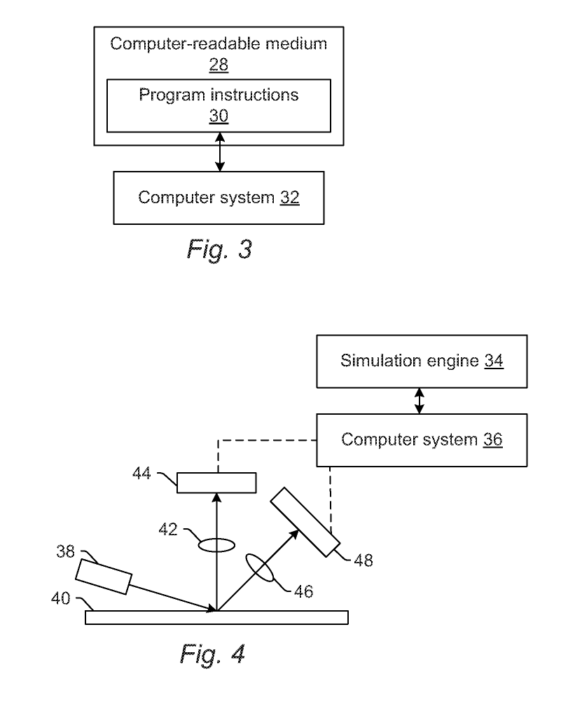

Another embodiment relates to a non-transitory computer-readable medium containing program instructions stored therein for causing a computer system to perform a computer-implemented method for determining one or more inspection parameters for a wafer inspection recipe. One embodiment of such a computer-readable medium is shown in FIG. 3. In particular, computer-readable medium 28 contains program instructions 30 stored therein for causing computer system 32 to perform a computer-implemented method for determining one or more inspection parameters for a wafer inspection recipe.

The computer-implemented method includes generating a 3D representation of one or more layers of a wafer based on design data, which may be performed as described herein. The computer-implemented method also includes determining one or more inspection parameters for a wafer inspection recipe based on the 3D representation, Determining the one or more inspection parameters may be performed as described herein. The computer-implemented method may include any other step(s) of any other method(s) described herein. In addition, the computer-readable medium may be further configured as described herein.

Program instructions 30 implementing methods such as those described herein may be stored on computer-readable medium 28. The computer-readable medium may be a non-transitory computer-readable storage medium such as a read-only memory, a random access memory, a magnetic or optical disk, a magnetic tape, or any other suitable computer-readable medium known in the art.

The program instructions may be implemented in any of various ways, including procedure-based techniques, component-based techniques, and/or object-oriented techniques, among others. For example, the program instructions may be implemented using ActiveX controls, C++ objects, JavaBeans, Microsoft Foundation Classes (“MFC”), or other technologies or methodologies, as desired.

Computer system 32 may take various forms, including a personal computer system, mainframe computer system, workstation, image computer, parallel processor, or any other device known in the art. In general, the term “computer system” may be broadly defined to encompass any device having one or more processors, which executes instructions from a memory medium.

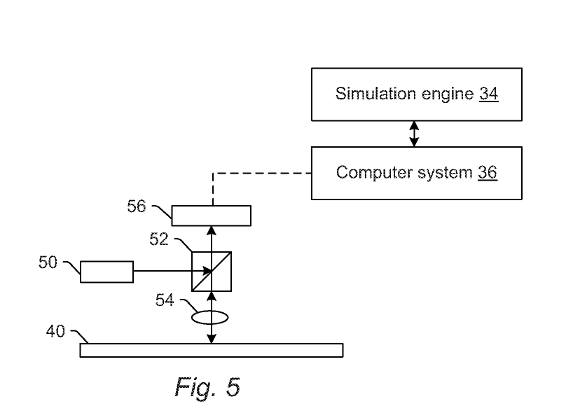

FIG. 4 illustrates one embodiment of a system configured to determine one or more inspection parameters for a wafer inspection recipe. The system includes simulation engine 34 configured to generate a 3D representation of one or more layers of a wafer based on design data. The simulation engine may include a graphical simulation engine, an inspection simulation engine, a simulation engine such as those included in the TCAD products commercially available from Synopsys, a simulation engine such as those included in the SCD-based products commercially available from KLA-Tencor, and the like. The simulation engine may be configured to generate the 3D representation as described further herein. In addition, the simulation engine may be configured to perform any other step(s) described herein.

The system also includes computer system 36 configured to determine one or more inspection parameters for a wafer inspection recipe based on the 3D representation. The computer system may be coupled to the simulation engine in any suitable manner such that the computer system can receive the 3D representation from the simulation engine. The computer system may be configured to determine the one or more inspection parameters according to any of the embodiments described herein. In addition, the computer system may be further configured as described herein and may be configured to perform any other step(s) described herein.

Computer system 36 may be configured as a stand-alone system that does not form part of a process, inspection, metrology, review, or other tool. In one such example, the system may include one or more components that are specifically designed (and optionally dedicated) to performing one or more of the computer-implemented methods described herein. In such an embodiment, computer system 36 may be configured to receive and/or acquire data or information from other systems (e.g., inspection results from an inspection system) by a transmission medium that may include “wired” and/or “wireless” portions. In this manner, the transmission medium may serve as a data link between the computer system and the other system. In addition, computer system 36 may send data to another system via the transmission medium. Such data may include, for example, one or more inspection parameters or any other information, parameters, etc. generated by the computer system described herein. Alternatively, computer system 36 may form part of a wafer inspection system, metrology system, defect review system, analysis system, or another tool.

The system may, however, also include a wafer inspection system configured to inspect the wafer using the wafer inspection recipe (e.g., to detect defects on the wafer and to acquire output for the defects and possibly also the wafer). The wafer inspection system may include an illumination subsystem. For example, as shown in FIG. 4, the illumination subsystem includes light source 38. Light source 38 may include any suitable light source known in the art such as a laser, arc lamp, or laser sustained plasma lamp. Light source 38 is configured to direct light to wafer 40 at an oblique angle of incidence, which may include any suitable oblique angle of incidence, or normal incidence through suitable optical elements. The illumination subsystem may also include one or more optical components (not shown) that are configured to direct light from light source 38 to wafer 40. The optical components may include any suitable optical components known in the art such as, but not limited to, a polarizing component or a polarizing rotation component. In addition, the light source and/or the one or more optical components may be configured to direct the light to the wafer at one or more angles of incidence (e.g., an oblique angle of incidence and/or a substantially normal angle of incidence).

Light scattered from wafer 40 may be collected and detected by multiple detection subsystems or multiple channels of the wafer inspection system. For example, light scattered from wafer 40 at angles relatively close to normal may be collected by lens 42 of one detection subsystem. Lens 42 may include a refractive optical element as shown in FIG. 4. In addition, lens 42 may include one or more refractive optical elements and/or one or more reflective optical elements. Light collected by lens 42 may be directed to detector 44 of that detection subsystem. Detector 44 may include any suitable detector known in the art such as a charge coupled device (CCD), photomuitiplier tube (PMT), or another type of imaging detector. Detector 44 is configured to generate output that is responsive to the light scattered from the wafer. Therefore, lens 42 and detector 44 form one channel of the wafer inspection system. This channel of the inspection system may include any other suitable optical components (not shown) known in the art such as a polarizing component and/or a Fourier filtering component. The wafer inspection system is configured to detect defects on the wafer using the output generated by detector 44. For example, a computer subsystem (e.g., computer system 36) of the wafer inspection system may be configured to detect defects on the wafer using the output generated by the detector.

Light scattered from wafer 40 at different angles may be collected by lens 46 of another detection subsystem. Lens 46 may be configured as described above. Light collected by lens 46 may be directed to detector 48 of this detection subsystem, which may be configured as described above. Detector 48 is also configured to generate output that is responsive to the light scattered from the wafer. Therefore, lens 46 and detector 48 may fonn another channel of the wafer inspection system. This channel may also include any other optical components described above. In some embodiments, lens 46 may be configured to collect light scattered from the wafer at polar angles from about 20 degrees to over 70 degrees. In addition, lens 46 may be configured as a reflective optical element (not shown) that is configured to collect light scattered from the wafer at azimuthal angles of about 360 degrees. The inspection system is configured to detect defects on the wafer using the output generated by detector 48, which may be performed as described above.

The wafer inspection system shown in FIG. 4 may also include one or more other channels. For example, the inspection system may include an additional channel (not shown), which may include any of the optical components described herein, configured as a side channel. In one such example, the side channel may be configured to collect and detect light that is scattered out of the plane of incidence (e.g., the side channel may include a lens that is centered in a plane that is substantially perpendicular to the plane of incidence and a detector configured to detect light collected by the lens). The inspection system may be configured to detect defects on the wafer using the output generated by a detector of the side channel.

The system also includes a computer subsystem (not shown) or may be coupled to and use computer system 36. For example, output generated by the detectors may be provided to computer system 36. For example, the computer system may be coupled to each of the detectors (e.g., by one or more transmission media shown by the dashed lines in FIG. 4, which may include any suitable transmission media known in the art) such that the computer system may receive the output generated by the detectors. The computer system may be coupled to each of the detectors in any suitable manner. Alternatively, computer system 36 may be coupled to a computer subsystem (not shown) of the inspection system such that the computer subsystem can receive wafer inspection parameters and/or a wafer inspection recipe generated by computer system 36. In addition, computer system 36 may receive any other output of the computer subsystem of the wafer inspection system such as image data and signals.

The system may also include a wafer inspection system configured to inspect the wafer using the wafer inspection recipe (e.g., to detect defects on the wafer and to acquire output for the defects and possibly also the wafer) such as that shown in FIG. 5. This wafer inspection system may include an illumination subsystem. For example, as shown in FIG. 5, the illumination subsystem includes light source 50, which may include any suitable light source. The illumination subsystem is configured to direct light to wafer 40 at a normal angle of incidence. For example, light from light source 50 may be directed to beam splitter 52, which may include any suitable beam splitter, Which directs the light to lens 54. Lens 54 may focus the light from the beam splitter to wafer 40 at a normal angle of incidence. The illumination subsystem may also include one or more other optical components (not shown) that are configured to direct light from light source 50 to wafer 40. The other optical components may include any suitable optical components known in the art such as, but not limited to, a polarizing component or a polarizing rotation component, in addition, the light source and/or the one or more optical components may be configured to direct the light to the wafer at one or more angles of incidence (e.g., an oblique angle of incidence and/or a substantially normal angle of incidence).

Light reflected from wafer 40 may be collected and detected by one or more detection subsystems or one or more channels of the wafer inspection system. For example, light reflected from wafer 40 may be collected by lens 54 of one detection subsystem. Lens 54 may include a refractive optical element as shown in FIG. 5. In addition, lens 54 may include one or more refractive optical elements and/or one or more reflective optical elements. Light collected by lens 54 may be directed through beamsplitter 52 to detector 56 of that detection subsystem. Detector 56 may include any suitable detectors known in the art such as a CCD, PMT, or another type of imaging detector. Detector 56 is configured to generate output that is responsive to the light reflected or scattered from the wafer. Therefore, lens 54 and detector 56 form one channel of the wafer inspection system. This channel of the inspection system may include any other suitable optical components (not shown) known in the art such as polarizing or filtering components. The wafer inspection system is configured to detect defects on the wafer using the output generated by detector 56. For example, a computer subsystem (e.g., computer system 36) of the wafer inspection system may be configured to detect defects on the wafer using the output generated by the detector.

The wafer inspection system shown in FIG. 5 may also include one or more other channels. For example, the inspection system may include an additional channel (not shown), which may include any of the optical components described herein, configured as a darkfieid channel configured to collect and detect light that is scattered from the wafer. The inspection system may be configured to detect defects on the wafer using the output generated by a detector of such a channel.

The system also includes a computer subsystem (not shown) or may be coupled to and use computer system 36. For example, output generated by detector 56 may be provided to computer system 36. in particular, the computer system may be coupled to the detector as described herein such that the computer system may receive the output generated by the detector. Alternatively, computer system 36 may be coupled to a computer subsystem (not shown) of the wafer inspection system as described further herein.

It is noted that FIGS. 4 and 5 are provided herein to generally illustrate configurations of a wafer inspection system that may be included in the system embodiments described herein. Obviously, the wafer inspection system configurations described herein may be altered to optimize the performance of the inspection systems as is normally performed when designing a commercial inspection system. In addition, the systems described herein may be implemented using an existing wafer inspection system (e.g., by adding functionality described herein to an existing inspection system) such as any of the wafer inspection tools that are commercially available from KLA-Tencor. For some such systems, the methods described herein may be provided as optional functionality of the system (e.g., in addition to other functionality of the system). Alternatively, the system described herein may be designed “from scratch” to provide a completely new system.

Further modifications and alternative embodiments of various aspects of the invention may be apparent to those skilled in the art in view of this description. For example, computer-implemented methods, computer-readable media, and systems for determining one or more inspection parameters for a wafer inspection recipe are provided, Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A computer-implemented method for determining one or more inspection parameters for a wafer inspection recipe, comprising:
generating a three-dimensional representation of one or more layers of a wafer based on design data; and
determining one or more inspection parameters for a wafer inspection recipe based on the three-dimensional representation, wherein said generating and said determining are performed by a computer system.

2. A non-transitory computer-readable medium containing program instructions stored therein for causing a computer system to perform a computer-implemented method for determining one or more inspection parameters for a wafer inspection recipe, wherein the computer-implemented method comprises:
generating a three-dimensional representation of one or more layers of a wafer based on design data; and
determining one or more inspection parameters for a wafer inspection recipe based on the three-dimensional representation.

3. A system configured to determine one or more inspection parameters for a wafer inspection recipe, comprising:
a simulation engine configured to generate a three-dimensional representation of one or more layers of a wafer based on design data; and
a computer system configured to determine one or more inspection parameters for a wafer inspection recipe based on the three-dimensional representation.
